(19) United States
(12) Patent Application Publication
(10) Pub. No.: US 2020/0016721 A1
(43) Pub. Date: Jan. 16, 2020

(54) SLURRY AND POLISHING METHOD

(71) Applicant: HITACHI CHEMICAL COMPANY, LTD., Tokyo (JP)

(72) Inventor: Mayumi OOUCHI, Chiyoda-ku, Tokyo (JP)

(21) Appl. No.: 16/334,807

(22) PCT Filed: Sep. 12, 2017
(86) PCT No.: PCT/JP2017/032914

§ 371 Date: Mar. 20, 2019

(30) Foreign Application Priority Data
Sep. 21, 2016 (JP) 2016-184351

(51) Int. Cl. B24B 37/005; C09G 1/02; C09K 3/14

(52) U.S. Cl. CPC B24B 37/0056; H01L 21/304; C09K 3/1409; C09G 1/02

(57) ABSTRACT

A slurry comprises abrasive grains, a glycol, and water, wherein an average particle diameter of the abrasive grains is 120 nm or smaller, and a pH is 4.0 or higher and lower than 8.0. A polishing method comprises a step of polishing a metal by use of the slurry.

### TECHNICAL FIELD

The present invention relates to a slurry and a polishing method.

### BACKGROUND ART

A CMP polishing liquid containing abrasive grains is occasionally stored as a stock solution having a content of the abrasive grains higher than that at the time of use, even in the case where the content of the abrasive grains is low which are contained in a CMP polishing liquid at the time of use, because of various kinds of reasons such as space saving for storage, the reduction of a transportation cost and the easy adjustment of the content; is used by being mixed with a medium (diluent) such as water or another additive liquid to dilute at the time of use. In this case, the higher is the content of the abrasive grains that are contained in the stock solution which has been concentrated, the higher the effect of concentration becomes.

As for a CMP polishing liquid to be used for metal polishing (CMP polishing liquid for metal), when a damascene process for forming embedded wiring in a substrate is taken as an example, there are known a polishing liquid for polishing a wiring metal (copper, tungsten, cobalt or the like) (hereinafter referred to as “CMP polishing liquid for wiring metal”), a polishing liquid for polishing a barrier film (hereinafter referred to as “CMP polishing liquid for barrier film”) for preventing a component constituting the wiring metal from diffusing into an interlayer insulating film, and the like.

As the above-described CMP polishing liquid for a wiring metal, there are known a CMP polishing liquid for stopping polishing on a barrier film, and a CMP polishing liquid for removing the barrier film and stopping the polishing on the interlayer insulating film. In these polishing liquids for the wiring metal, there is a tendency that abrasive grains having a smaller particle diameter are used as the wiring becomes finer in recent years.

As for the CMP polishing liquid for the barrier film, there are known a highly selective CMP polishing liquid for the barrier film, which polishes the barrier film in preference to other members, and a non-selective CMP polishing liquid for the barrier film, which polishes not only the barrier film but also a part of the interlayer insulating film under the barrier film. The non-selective CMP polishing liquid for the barrier film is required to polish not only the barrier film but also the interlayer insulating film at a high speed, and the content of the abrasive grains is generally increased in many cases, so as to increase a polishing rate for an interlayer insulating film.

Thus, for a stock solution which is used for obtaining the CMP polishing liquid, and for the CMP polishing liquid, for instance, there is a case where the content of the abrasive grains becomes high and the particle diameter of the contained abrasive grains becomes small, due to various requirements.

A possibility that the abrasive grains agglomerate and settle down becomes high, depending on conditions such as a storage period of time and a storage temperature, and accordingly it is necessary to enhance the dispersion stability of the abrasive grains in order to avoid the agglomeration of the abrasive grains. As a method for enhancing the dispersion stability of the abrasive grains, there are known a method of increasing a zeta potential of the abrasive grains in the CMP polishing liquid to a positive potential or a negative potential and increasing the electrostatic repulsive force among the abrasive grains (for instance, refer to Patent Literature 1), and a method of adding an additive such as an amino group-containing silane coupling agent which contributes to the dispersion stabilization of the abrasive grains (for instance, refer to Patent Literature 2), and a method of setting the storage temperature at a low temperature of about 5 to 10° C.

### CITATION LIST

### Patent Literature

Patent Literature 1: Japanese Unexamined Patent Publication No. 2004-172338

Patent Literature 2: Japanese Unexamined Patent Publication No. 2008-288398

### SUMMARY OF INVENTION

### Technical Problem

However, even when the dispersion stability of the abrasive grains has been enhanced by such a method, if the abrasive grains become finer, the possibility becomes high that the abrasive grains agglomerate and settle down, no matter how the storage conditions have been tried to adjust. For instance, in the method of increasing the zeta potential of the abrasive grains in the CMP polishing liquid to the positive potential or the negative potential, there are such restrictions that it is difficult to change only the zeta potential of the abrasive grains while keeping the blending ratio of components other than the abrasive grains constant, and it is impossible to select the type of abrasive grains only for changing the zeta potential because the type of abrasive grains affects the polishing characteristics.

The present invention has been designed with respect to the above circumstances, and an object is to provide a slurry that is excellent in the dispersion stability of abrasive grains while using abrasive grains having a small particle diameter, and a polishing method using the slurry.

### Solution to Problem

The slurry of the present invention comprises abrasive grains, a glycol, and water, wherein an average particle diameter of the abrasive grains is 120 nm or smaller, and a pH is 4.0 or higher and lower than 8.0.

The slurry of the present invention is excellent in the dispersion stability of abrasive grains while using abrasive grains having a small particle diameter. For instance, according to the slurry of the present invention, it is possible to greatly suppress agglomeration/sedimentation of the abrasive grains even when a content of the abrasive grains is high or even when the slurry has been stored not at low temperature but at about room temperature (for instance, 0° C. to 60° C.); and is high in storage convenience.

In the case of a method for enhancing the dispersion stability of the abrasive grains by adding an additive (for instance, Patent Literature 2), there is a case where polishing characteristics are affected by adding a necessary amount of the additive so that a sufficient dispersion effect of abrasive grains can be obtained. For instance, if a large amount of an additive is added to a CMP polishing liquid for a barrier film, there is a case where a polishing rate for an insulating material is extremely lowered. In contrast, the slurry of the present invention is excellent in the dispersion stability of the abrasive grains, and accordingly can easily maintain the effect of improving polishing characteristics such as the polishing rate and flatness, even in the case where other components have been added.

In addition, in the case of a method for enhancing the dispersion stability of the abrasive grains by lowering the storage temperature of the CMP polishing liquid, an apparatus and a space for storage at low temperature are needed, which imposes a burden on the process and the cost. In contrast, the slurry of the present invention does not need such an apparatus and a space for the storage at low temperature, and accordingly can flexibly cope with a reduction of the process or the cost.

It is preferable that the pH of the slurry of the present invention is higher than 5.0 and lower than 8.0.

It is preferable that the abrasive grains comprise silica. It is preferable that the mass ratio of a content of the abrasive grains with respect to a content of the glycol is 0.01 to 150.

It is preferable that the glycol in the slurry of the present invention comprises a glycol in which the number of carbon atoms of an alkylene group between two hydroxy groups is 5 or less. The glycol preferably comprises at least one selected from the group consisting of ethylene glycol, 1,2-butanediol, 1,3-butanediol, 1,4-butanediol and 1,5-pentanediol, and more preferably comprises ethylene glycol.

It is preferable that the slurry of the present invention further comprises an organic acid component. The slurry of the present invention may further comprise a metal corrosion preventive agent.

The slurry of the present invention may be for use in polishing a cobalt-based metal. According to the slurry of the present invention, it is possible to suitably polish the cobalt-based metal.

The polishing method of the present invention comprises a step of polishing a metal by use of the above-described slurry. According to the polishing method of the present invention, it is possible to provide a semiconductor substrate or an electronic device which is prepared by use of the polishing method. The semiconductor substrate and other electronic devices that have been prepared in this way can be miniaturized and thinned, and also have high reliability while being excellent in dimensional precision and electrical characteristics.

In the polishing method of the present invention, the metal may comprise a cobalt-based metal. According to the polishing method of the present invention, it is possible to suitably polish the cobalt-based metal.

### Advantageous Effects of Invention

According to the present invention, it is possible to provide a slurry that is excellent in the dispersion stability of abrasive grains while using abrasive grains having a small particle diameter, and a polishing method using the slurry.

### DESCRIPTION OF EMBODIMENTS

Embodiments for carrying out the present invention will be described in detail below. However, the present invention is not limited to the following embodiments.

### Definition

In the present specification, a numerical range that has been indicated by use of “to” indicates the range that includes the numerical values which are described before and after “to”, as the minimum value and the maximum value, respectively. In the numerical ranges that are described stepwise in the present specification, the upper limit value or the lower limit value of the numerical range of a certain stage can be arbitrarily combined with the upper limit value or the lower limit value of the numerical range of another stage. In the numerical ranges that are described in the present specification, the upper limit value or the lower limit value of the numerical value range may be replaced with the value shown in the examples. “A or B” may include either one of A and B, and may also include both of A and B. Materials listed as examples in the present specification can be used singly or in combinations of two or more, unless otherwise specifically indicated. In the present specification, when a plurality of substances corresponding to each component exist in the composition, the content of each component in the composition means the total amount of the plurality of substances that exist in the composition, unless otherwise specified.

<Slurry>

A slurry of the present embodiment comprises abrasive grains, glycol and water; an average particle diameter of the abrasive grains is 120 nm or smaller; and a pH is 4.0 or more and less than 8.0. The slurry of the present embodiment may be used as a CMP polishing liquid in the state without being mixed with a diluent or an additive liquid, or may be used as the CMP polishing liquid by being mixed with a diluent or an additive liquid. In other words, the slurry of the present embodiment can be used as the CMP polishing liquid, and can be used in order to obtain the CMP polishing liquid; and for instance, can be used as the CMP polishing liquid to be used for polishing in a wiring formation step of a semiconductor substrate or the like, and can be used in order to obtain such a CMP polishing liquid. The “additive liquid” is defined as a liquid containing an additive, where the additive may be completely dissolved, or at least a part of the additive may exist as a solid.

(Abrasive Grain)

Examples of components constituting the abrasive grains include silica, alumina, ceria, titania, zirconia, germania, and modified substances thereof. It is preferable that the abrasive grains contain silica, from the viewpoint that polishing scratches are easily suppressed. The components constituting the abrasive grains can be used singly, or in combinations of two or more.

As for the abrasive grains containing silica (hereinafter referred to as “silica particles”), known particles such as fumed silica and colloidal silica can be used. As for the silica particles, colloidal silica is preferable from the viewpoint that silica particles having the below-mentioned average particle diameter, degree of association, zeta potential, and density of silanol groups are easily available.

The average particle diameter of the abrasive grains is 120 nm or smaller, from the viewpoint that the polishing scratches are easily suppressed and the dispersion stability of the abrasive grains is excellent. The average particle diameter of the abrasive grains is preferably 5 to 120 nm, more preferably 5 to 100 nm, and further preferably 10 to 90 nm, from the viewpoint that a favorable polishing rate is easily obtained; and is particularly preferably 10 to 80 nm, extremely preferably 10 to 50 nm, very preferably 10 to 30 nm, and still further preferably 10 to 25 nm, from the viewpoint that a favorable polishing selection ratio (metal/insulating material, wiring metal/barrier metal, and the like) is easily obtained.

The average particle diameter of the abrasive grains is a value (secondary particle diameter) which has been measured with a dynamic light scattering type particle size distribution meter (for instance, made by BECKMAN COULTER Inc., trade name: Model COULTER N5). Measurement conditions of COULTER are such conditions that a measurement temperature is 20° C., a solvent refractive index is 1.333 (corresponding to water), a refractive index of the particle is Unknown (set), a solvent viscosity is 1.005 mPa-s (corresponding to water), Run Time is 200 sec, and an incident angle of a laser is 90°; Intensity (corresponding to scattering intensity or turbidity) is adjusted so as to be within a range of 5E+04 to 1E+06 to measure; and dilution is performed with water if it is higher than 1E+06.

The degree of association of the abrasive grains is preferably 1.1 or more, more preferably 1.2 or larger, further preferably 1.3 or larger, and particularly preferably 1.4 or larger, from the viewpoint that the favorable polishing rate for an insulating material can be easily obtained.

The “degree of association” means a value (average particle diameter/biaxial average primary particle diameter) that is obtained by determining the “average particle diameter (secondary particle diameter)” of the secondary particles, which has been measured by the particle size distribution meter by the dynamic light scattering method, in a state in which the abrasive grains are dispersed in the liquid as described above, and by dividing this average particle diameter by the biaxial average primary particle diameter.

The zeta potential of the abrasive grains in the slurry is preferably +5 mV or higher, and more preferably +10 mV or higher, from the viewpoint that dispersion stability of the abrasive grains is further excellent, and the favorable polishing rate for an insulating material can be easily obtained. The upper limit of the zeta potential is not limited in particular, but as long as the upper limit is about 80 mV or lower, the upper limit is sufficient in ordinary polishing.

The zeta potential (C [mV]) is measured by diluting the slurry with pure water so that the scattering intensity of the measurement sample becomes 1.0×10⁴ to 5.0×10⁴ cps (here, “cps” means counts per second, and is a unit of counting of particles) in a zeta potential measuring apparatus; and adding it into a cell for zeta potential measurement. Examples of methods for setting the scattering intensity within the above-described range include a method of adjusting (diluting or the like) the slurry so that abrasive grains (silica particles or the like) become 1.7 to 1.8 mass %.

When the abrasive grains contain silica particles, the density of silanol groups in the silica particles is preferably 5.0 pieces/nm² or less, more preferably 4.5 pieces/nm² or less, and further preferably 1.5 pieces/nm² or more and 4.5 pieces/nm² or less, from the viewpoint that a favorable polishing selection ratio of metal/insulating material is obtained in the cases where the CMP polishing liquid is used, and that excellent dispersion stability can be easily obtained by being used in combination with glycol.

The density of the silanol group (ρ [pieces/nm²]) can be measured and calculated by the following titration.

[1] Weigh out silica particles (colloidal silica or the like) into a polybottle so that the silica particles become 15 g.

[2] Add 0.1 mol/L of hydrochloric acid in order to adjust the pH to 3.0 to 3.5. At this time, the mass [g] of 0.1 mol/L of the added hydrochloric acid is also measured.

[3] Calculate the mass of the mixture for which the pH adjustment has been completed in [2] (silica particles and 0.1 mol/L of hydrochloric acid; excluding polybottle).

[4] Weigh out an aliquot corresponding to 1/10 of the mass obtained in [3] to another polybottle.

[5] Add 30 g of sodium chloride thereto, and further add ultrapure water thereto to adjust the total amount to 150 g.

[6] Adjust its pH to 4.0 by 0.1 mol/L of a sodium hydroxide solution to obtain a sample for titration.

[7] Add 0.1 mol/L of the sodium hydroxide solution dropwise to this sample for titration until the pH reaches 9.0, and determine the amount of sodium hydroxide which has been needed when the pH has reached 9.0 from 4.0 (B [mol]).

[8] Calculate the density of the silanol groups in the silica particles from the following expression (1).

ρ=B×NA/A×S_{BET} (1)

[Here, NA [pieces/mol] in expression (1) represents Avogadro's number, A [g] represents an amount of the silica particles, and S_{BET} [m²/g] represents a BET specific surface area of the silica particles, respectively.]

The BET specific surface area S_{BET} of the above-described silica particles can be determined according to the BET specific surface area method. As for the specific measurement method, for instance, it is possible to determine by subjecting a sample which has been prepared by adding silica particles (colloidal silica or the like) into a dryer, followed by drying at 150° C., then adding them into a measurement cell and performing vacuum-degassing at 120° C. for 60 minutes, to a one-point method or a multipoint method for nitrogen gas adsorption by use of a BET specific surface area measuring apparatus. More specifically, the BET specific surface area S_{BET} is measured by adding a sample for measurement, which has been prepared by finely crushing the dried particles at 150° C. in a mortar (made from porcelain, and 100 mL), into a measurement cell and adding them in a BET specific surface area measuring apparatus (made by Yuasa Ionics Inc., trade name: NOVE-1200).

The details of the above-described method for calculating the density of the silanol groups are disclosed, for instance, in Analytical Chemistry, 1956, vol. 28, No. 12, p. 1981 to 1983, and Japanese Journal of Applied Physics, 2003, Vol. 42, p. 4992 to 4997.

The content of abrasive grain (for instance, content at the time of storing as stock solution) is preferably 0.1 mass % or more, more preferably 0.3 mass % or more, further preferably 0.5 mass % or more, particularly preferably 0.7 mass % or more, extremely preferably 1.0 mass % or more, and very preferably 3.0 mass % or more, on the basis of the total mass of the slurry, from the viewpoint that a favorable polishing rate can be easily obtained. The content of the abrasive grain is preferably 20 mass % or less, more preferably 10 mass % or less, further preferably 7.5 mass % or less, and particularly preferably 5.0 mass % or less, on the basis of the total mass of the slurry, from the viewpoint that there is a tendency that the agglomeration/sedimentation of the particles are further easily suppressed, and as a result, further favorable dispersion stability and storage stability are obtained.

(Glycol)

The slurry of the present embodiment comprises a glycol as an organic solvent, from the viewpoint that the dispersion stability of the abrasive grains is extremely favorable and the storage stability is excellent. The reason why such an effect is obtained is not exactly clear, but is presumed to be the following.

Specifically, a hydrogen bond is formed between a hydroxyl group (—OH) which the glycol has and the abrasive grain, and the glycol surrounds the abrasive grain by a phenomenon similar to the solvation. In addition, the glycol efficiently interacts with the abrasive grain due to two hydroxy groups, and accordingly it is considered that the glycol can suppress the approach of the abrasive grains to each other and can suppress the agglomeration and sedimentation of the abrasive grains.

When the abrasive grains include silica particles, a hydrogen bond is formed between the hydroxyl group which the glycol has and the silanol group (—Si—OH) of the abrasive grain, and the glycol tends to easily surround the abrasive grain by a phenomenon similar to the solvation. In addition, the glycol efficiently interacts with the silanol group of the abrasive grain due to two hydroxy groups, and accordingly it is considered that the glycol can suppress the approach of the abrasive grains to each other and can further suppress the agglomeration and sedimentation of the abrasive grains.

Specifically, it is considered that an organic solvent having few hydroxy groups (no or one hydroxy group) or an organic solvent having many hydroxy groups (three or more hydroxy groups) causes a phenomenon such as the solvation, but is difficult to effectively separate the abrasive grains from each other. The glycol is high in miscibility with water, and can effectively suppress the agglomeration/sedimentation of the abrasive grains.

The glycol is also referred to as dialcohol, and shows a compound having two hydroxy groups. It is preferable that the slurry of the present embodiment comprises a glycol in which the number of carbon atoms of an alkylene group between two hydroxy groups is 5 or less, from the viewpoint that a further excellent dispersion stability of the abrasive grains is obtained. “The number of carbon atoms of an alkylene group between two hydroxy groups” does not include carbon atoms of a side chain in the molecular chain between the two hydroxy groups. The number of carbon atoms of an alkylene group between the two hydroxy groups may be 4 or less, 3 or less, and 2 or less.

Examples of the glycol include: ethylene glycol (1,2-ethanediol), propylene glycol (1,2-propanediol), 1,3-propanediol, 1,2-butanediol, 1,3-butanediol, 1,4-butanediol, 1,4-pentanediol, 1,5-pentanediol, 1,5-hexanediol, 1,6-hexanediol, diethylene glycol, dipropylene glycol, triethylene glycol, and tripropylene glycol. The glycol is preferably at least one selected from the group consisting of ethylene glycol, 1,2-butanediol, 1,3-butanediol, 1,4-butanediol and 1,5-pentane diol, and more preferably ethylene glycol, from the viewpoint that a further excellent dispersion stability of the abrasive grains is obtained. The glycols can be used singly, or in combinations of two or more.

The content of the glycol is preferably 0.1 mass % or more, more preferably 0.3 mass % or more, further preferably 0.5 mass % or more, particularly preferably 1.0 mass % or more, extremely preferably 1.5 mass % or more, very preferably 3.0 mass % or more, and still further preferably 5.0 mass % or more, on the basis of the total mass of the slurry, from the viewpoint that a further excellent dispersion stability of the abrasive grains is obtained. The content of the glycol is preferably 20 mass % or less, more preferably 15 mass % or less, and further preferably 10 mass % or less, on the basis of the total mass of the slurry, from the viewpoint that a further excellent dispersion stability of the abrasive grains is obtained.

The mass ratio of the content of the abrasive grain with respect to the content of the glycol (content of abrasive grain/content of glycol) is preferably 150 or less, more preferably 100 or less, further preferably 10 or less, particularly preferably 5 or less, and extremely preferably 4 or less, from the viewpoint that the glycol further suppresses the approach of the abrasive grains to each other and further suppresses the agglomeration and sedimentation of the abrasive grains. It is considered that, as long as it is within these ranges, a sufficient amount of glycol exists for one abrasive grain; and the glycol successfully surrounds the periphery of the abrasive grain, and a phenomenon such as the solvation can be easily and successfully obtained to keep the dispersion stability of the abrasive grains. It is preferable that the mass ratio of the content of the abrasive grain with respect to the content of the glycol is 0.01 or more, from the viewpoint of suppressing salting-out and the like due to excessive addition of a component other than water in the solvent. The mass ratio of the content of the abrasive grain with respect to the content of the glycol may be 0.1 or more, 1 or more, and 3 or more. From these viewpoints, it is preferable that the mass ratio of the content of the abrasive grain with respect to the content of the glycol is 0.01 to 150.

It is preferable that the following change rate of the average particle diameter of the abrasive grains after the slurry comprising the abrasive grains and the glycol has been stored at 60° C. for 14 days is 9% or less. The average particle diameter of the abrasive grains can be measured by a light diffraction scattering type particle size distribution meter, as has been described above.

Change Rate (%) of average particle diameter of abrasive grains: (average particle diameter after storage at 60° C. for 14 days−initial average particle diameter)/(initial average particle diameter)×100

(Water)

The slurry of the present embodiment comprises water as a liquid medium. The water is not limited in particular, but pure water is preferable. The water may be added as a remainder of the components constituting the slurry, and the content of the water is not limited in particular.

(Additive)

The slurry of the present embodiment may comprise an additive other than the abrasive grain, the glycol and the water. As the additive, it is possible to use an additive which is used for a general polishing liquid for metal, and the examples include: an organic acid component, a metal corrosion preventive agent, a metal oxidizing agent, an organic solvent (excluding glycol), a pH adjusting agent (acid component (excluding organic acid component), an alkali component and the like), a dispersing agent, a surfactant, and a water-soluble polymer (polymer (homopolymer, copolymer or the like) having structural unit derived from (meth)acrylic acid).

[Organic Acid Component]

It is preferable that the slurry of the present embodiment comprises an organic acid component, from the viewpoint that favorable polishing rates for metals such as wiring metals and barrier metals are further easily obtained. The organic acid component can have an effect as a metal oxide dissolving agent. Here, the “organic acid component” is defined as a substance which contributes to dissolving at least metal into water, and contains a substance known as a chelating agent or an etching agent.

The organic acid components can be used singly, or in combinations of two or more. The organic acid components have an effect of improving the polishing rates for wiring metals and barrier metals (cobalt-containing portion and the like). Examples of the organic acid components include organic acids, salts of organic acids, anhydrides of organic acids, and esters of organic acids. Examples of the organic acids include carboxylic acids (excluding compounds corresponding to amino acids), and amino acids.

Examples of the carboxylic acids include: formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, salicylic acid, o-toluic acid, m-toluic acid, p-toluic acid, glycolic acid, diglycolic acid, mandelic acid, quinaldic acid, quinolinic acid, glyceric acid, oxalic acid, malonic acid, succinic acid, glutaric acid, gluconic acid, adipic acid, pimelic acid, maleic acid, fumaric acid, malic acid, tartaric acid, citric acid and phthalic acid; alkylphthalic acids such as 3-methylphthalic acid, 4-methylphthalic acid and 4-ethylphthalic acid; amino phthalic acids such as 3-aminophthalic acid and 4-amninophthalic acid; and nitrophthalic acids such as 3-nitrophthalic acid and 4-nitrophthalic acid.

The carboxylic acid is preferably a dicarboxylic acid having a hydrophobic group (such as an alkyl group), and more preferably a dicarboxylic acid having a hydrophobic group and an aromatic ring, from the viewpoint that a favorable polishing rate for metal and a low etching rate for metal tend to be easily achieved.

Examples of the amino acids include: glycine, α-alanine, β-alanine, 2-aminobutyric acid, norvaline, valine, leucine, norleucine, isoleucine, alloisoleucine, phenylalanine, proline, sarcosine, ornithine, ricin, serine, threonine, allothreonine, homoserine, tyrosine, 3,5-diiodotyrosine, β-(3,4-dihydroxyphenyl)-alanine, thyroxine, 4-hydroxyproline, cysteine, methionine, ethionine, lanthionine, cystathionine, cystine, cysteic acid, aspartic acid, glutamic acid, S-(carboxymethyl)-cysteine, 4-aminobutyric acid, asparagine, glutamine, azaserine, arginine, canavanine, citrulline, S-hydroxylysine, creatine, kynurenine, histidine, 1-methylhistidine, 3-methylhistidine, ergothioneine and tryptophan.

The content of the organic acid components is preferably 20 mass % or less, more preferably 15 mass % or less, further preferably 10 mass % or less, and particularly preferably 5.0 mass % or less, on the basis of the total mass of the slurry, from the viewpoint that the etching rate is easily suppressed. The content of the organic acid components is preferably 0.5 mass % or more, and more preferably 1.0 mass % or more, on the basis of the total mass of the slurry, from the viewpoint that a favorable polishing rate for a metal is easily obtained.

[Metal Corrosion Preventive Agent]

The slurry of the present embodiment may comprise a metal corrosion preventive agent, from the viewpoint that corrosion of metals is more effectively suppressed. The metal corrosion preventive agent is not limited in particular, and it is possible to use any conventionally known compound as a compound having a corrosion preventive effect against metals. As metal corrosion preventive agents, specifically, it is possible to use at least one selected from the group consisting of a triazole compound, a pyridine compound, a pyrazole compound, a pyrimidine compound, an imidazole compound, a guanidine compound, a thiazole compound, a tetrazole compound, a triazine compound, and hexamethylenetetramine. Here, the above-described “compound” is a collective term for compounds having a skeleton thereof and for instance, the “triazole compound” means a compound having a triazole skeleton. Arecoline can also be used as the metal corrosion preventive agent. The metal corrosion preventive agent can be used singly, or in combinations of two or more.

Examples of the triazole compounds include 1,2,3-triazole, 1,2,4-triazole, 3-amino-1H-1,2,4-triazole, benzotriazole (BTA), 1-hydroxybenzotriazole, 1-hydroxypropylbenzotriazole, 2,3-dicarboxypropylbenzotriazole, 4-hydroxybenzotriazole, 4-carboxy-1H-benzotriazole, 4-carboxy-1H-benzotriazole methyl ester (methyl 1H-benzotriazole-4-carboxylate), 4-carboxy-1H-benzotriazole butyl ester (butyl 1H-benzotriazole-4-carboxylate), 4-carboxy-1H-benzotriazole octyl ester (octyl 1H-benzotriazole-4-carboxylate), 5-methylbenzotriazole, 5-hexylbenzotriazole, (1,2,3-benzotriazolyl-1-methyl) (1,2,4-triazolyl-1-methyl) (2-ethylhexyl)amine, tolyltriazole, naphthotriazole, bis[(1-benzotriazolyl)methyl]phosphonic acid, 3H-1,2,3-triazolo[4,5-b]pyridin-3-ol, 1H-1,2,3-triazolo[4,5-b]pyridine, 1-acetyl-1H-1,2,3-triazolo[4,5-b]pyridine, 3-hydroxypyridine, 1,2,4-triazolo[1,5-a]pyrimidine, 1,3,4,6,7,8-hexahydro-2H-pyrimido[1,2-a]pyrimidine, 2-methyl-5,7-diphenyl-1,2,4]triazolo[1,5-a]pyrimidine, 2-methylsulfanyl-5,7-diphenyl-[1,2,4]triazolo[1,5-a]pyrimidine, and 2-methylsulfanyl-5,7-diphenyl-4,7-dihydro-[1,2,4]triazolo[1,5-a]pyrimidine. When a triazole skeleton and another skeleton are contained in one molecule, the compound shall be classified into a triazole compound.

Examples of the pyridine compounds include 8-hydroxyquinoline, protionamide, 2-nitropyridin-3-ol, pyridoxamine, nicotinamide, iproniazid, isonicotinic acid, benzo[f]quinoline, 2,5-pyridinedicarboxylic acid, 4-styrylpyridine, anabasine, 4-nitropyridine-1-oxide, ethyl 3-pyridylacetate, quinoline, 2-ethylpyridine, quinolinic acid, citrazinic acid, pyridine-3-methanol, 2-methyl-5-ethylpyridine, 2-fluoropyridine, pentafluoropyridine, 6-methylpyridin-3-ol, and ethyl 2-pyridylacetate.

Examples of the pyrazole compounds include pyrazole, 1-allyl-3,5-dimethylpyrazole, 3,5-di(2-pyridyl)pyrazole, 3,5-diisopropylpyrazole, 3,5-dimethyl-1-hydroxymethylpyrazole, 3,5-dimethyl-1-phenylpyrazole, 3,5-dimethylpyrazole, 3-amino-5-hydroxypyrazole, 4-methylpyrazole, N-methylpyrazole, and 3-aminopyrazole.

Examples of the pyrimidine compounds include pyrimidine, 1,3-diphenyl-pyrimidine-2,4,6-trione, 1,4,5,6-tetrahydropyrimidine, 2,4,5,6-tetraaminopyrimidine sulfate, 2,4,5-trihydroxypyrimidine, 2,4,6-triaminopyrimidine, 2,4,6-trichloropyrimidine, 2,4,6-trimethoxypyrimidine, 2,4,6-triphenylpyrimidine, 2,4-diamino-6-hydroxylpyrimidine, 2,4-diaminopyrimidine, 2-acetamidopyrimidine, 2-aminopyrimidine, and 4-aminopyrazolo[3,4-d]pyrimidine.

Examples of the imidazole compounds include 1,1′-carbonylbis-1H-imidazole, 1,1′-oxalyldiimidazole, 1,2,4,5-tetramnethylimidazole, 1,2-dimethyl-5-nitroimidazole, 1,2-dimethylimidazole, 1-(3-aminopropyl)imidazole, 1-butylimidazole, 1-ethylimidazole, 1-methylimidazole and benzimidazole.

Examples of the guanidine compounds include 1,1,3,3-tetramethylguanidine, 1,2,3-triphenylguanidine, 1,3-di-o-tolylguanidine and 1,3-diphenylguanidine.

Examples of the thiazole compounds include 2-mercaptobenzothiazole and 2,4-dimethylthiazole.

Examples of the tetrazole compounds include tetrazole, 5-methyltetrazole, 5-amino-1H-tetrazole, 1-(2-dimethylaminoethyl)-5-mercaptotetrazole, 1,5-pentamethylenetetrazole, and 1-(2-dimethylaminoethyl)-5-mercaptotetrazole.

Examples of the triazine compounds include 3,4-dihydro-3-hydroxy-4-oxo-1,2,4-triazine.

The metal corrosion preventive agent is preferably at least one selected from the group consisting of a triazole compound (such as benzotriazole compound), a pyridine compound, a pyrazole compound, an imidazole compound, a thiazole compound (such as benzothiazole compound) and a tetrazole compound, from the viewpoint that corrosion is easily and effectively suppressed while appropriate polishing rates for wiring metals and barrier metals (such as cobalt-containing portion) are kept; more preferably at least one selected from the group consisting of the triazole compound (such as benzotriazole compound), the pyridine compound and the tetrazole compound; and further preferably at least one selected from the group consisting of the pyridine compound and the benzotriazole compound.

The content of the metal corrosion preventive agents is preferably 0.01 mass % or more, more preferably 0.05 mass % or more, and further preferably 0.1 mass % or more, on the basis of the total mass of the slurry, from the viewpoint of easily suppressing etching of the metal and easily suppressing roughening of a polished surface. The content of the metal corrosion preventive agent is preferably 10 mass % or less, more preferably 5 mass % or less, further preferably 3 mass % or less, particularly preferably 2 mass % or less, extremely preferably 1 mass % or less, and very preferably 0.5 mass % or less, on the basis of the total mass of the slurry, from the viewpoint that the polishing rates for wiring metals and barrier metals are easily kept at more practical polishing rates.

[Metal Oxidizing Agent]

The metal oxidizing agent is not limited in particular as long as the metal oxidizing agent has a capability of oxidizing the metal, and specific examples thereof include hydrogen peroxide, nitric acid, potassium periodate, hypochlorous acid and ozone water; and among them, the hydrogen peroxide is particularly preferable. The metal oxidizing agents can be used singly, or in combinations of two or more.

When a substrate is a silicon substrate containing an element for an integrated circuit, contamination with an alkali metal, an alkaline earth metal, a halide or the like is not preferable, and accordingly an oxidizing agent which does not contain a nonvolatile component is preferable. However, the composition of the ozone water shows an intense change with time, and accordingly the hydrogen peroxide is the most suitable. In the case where the base material to be applied is a glass substrate or the like which does not contain the semiconductor element, it may be an oxidizing agent which contains a nonvolatile component.

The content of the metal oxidizing agent is preferably 0.01 mass % or more, more preferably 0.02 mass % or more, and further preferably 0.05 mass % or more, on the basis of the total mass of the slurry, from the viewpoint of easily suppressing insufficient oxidation of a metal for suppressing the lowering of the CMP rate. The content of the metal oxidizing agent is preferably 50 mass % or less, more preferably 30 mass % or less, and further preferably 10 mass % or less, on the basis of the total mass of the slurry, from the viewpoint of easily suppressing roughening of a polished surface. When the hydrogen peroxide is used as the oxidizing agent, the hydrogen peroxide is usually available as oxygenated water, and accordingly the oxygenated water is blended so that the hydrogen peroxide finally becomes within the above descried range.

(pH)

The pH of the slurry of the present embodiment is 4.0 or higher, from the viewpoint that the excellent dispersion stability of the abrasive grains can be easily obtained. In addition, when the pH is 4.0 or higher, favorable polishing rates for wiring metals, barrier metals and insulating materials are easily obtained, a favorable polishing selection ratio of the wiring metals with respect to the insulating materials is easily obtained, and corrosion and etching of the wiring metals are easily suppressed. The pH of the slurry is preferably higher than 4.0, more preferably 5.0 or higher, further preferably higher than 5.0, particularly preferably 5.3 or higher, extremely preferably 5.5 or higher, very preferably 6.0 or higher, and still further preferably 6.5 or higher, from the viewpoint that the excellent dispersion stability of the abrasive grains can be further easily obtained, the favorable polishing rates for wiring metals, barrier metals and insulating materials can be further easily obtained, the favorable polishing selection ratio of the wiring metals with respect to the insulating materials can be further easily obtained, and the corrosion and etching of the wiring metals are further easily suppressed.

The pH of the slurry of the present embodiment is lower than 8.0, from the viewpoint that the excellent dispersion stability of the abrasive grains can be easily obtained. The pH of the slurry of the present embodiment is preferably 7.5 or lower, and more preferably 7.0 or lower, from the viewpoint that the excellent dispersion stability of the abrasive grains can be further easily obtained, and the favorable polishing rate for the metal can be easily obtained.

From these viewpoints, the pH of the slurry of the present embodiment is preferably higher than 4.0 and lower than 8.0, more preferably 5.0 or higher and lower than 8.0, further preferably higher than 5.0 and lower than 8.0, particularly preferably 5.3 or higher and lower than 8.0, extremely preferably 5.5 or higher and lower than 8.0, very preferably 6.0 or higher and 7.5 or lower, and still further preferably 6.5 or higher and 7.0 or lower.

The pH can be adjusted by an amount of the acid component to be added. In addition, the pH can also be adjusted by addition of an alkaline component such as ammonia, sodium hydroxide, potassium hydroxide and tetramethylammonium hydroxide (TMAH).

The pH of the slurry can be measured by use of a pH meter (for instance, Model F-51 made by Horiba Ltd. (HORIBA, Ltd.)). Specifically, after performing three-point calibration by use of standard buffer solutions (phthalate pH buffer solution, pH: 4.01 (25° C.); neutral phosphate pH buffer solution, pH: 6.86 (25° C.); and borate pH buffer solution, pH: 9.18 (25° C.)), it is possible to measure by charging an electrode into the slurry, and regarding a value after the value has become stabilized after 3 minutes or longer have passed, as the pH. The pH is defined as the pH at a liquid temperature of 25° C.

<Polishing Method>

The polishing method of the present embodiment comprises a polishing step of polishing an object to be polished, by use of the slurry of the present embodiment, and for instance, comprises a step of polishing a metal as an object to be polished, by use of the slurry of the present embodiment. Examples of the metal include a wiring metal and a barrier metal. Examples of the wiring metals include: copper-based metals such as copper, copper alloys, oxides of copper, and oxides of the copper alloys; tungsten-based metals such as tungsten, tungsten nitride and tungsten alloys; cobalt-based metals such as cobalt, cobalt alloys, oxides of cobalt, cobalt alloys, and oxides of the cobalt alloys; silver; and gold. Examples of the components constituting the barrier metals include tantalum-based metals, titanium-based metals, tungsten-based metals, ruthenium-based metals, cobalt-based metals and manganese-based metals. The metals such as the tungsten-based metals and the cobalt-based metals can be used for both the wiring metals and the barrier metals. The polishing liquid of the present embodiment can be suitably used for polishing the cobalt-based metals, and it is possible to suitably polish the cobalt-based metals by use of the slurry of the present embodiment, in a polishing step in the polishing method of the present embodiment. The polishing step may also be a step of polishing the above-described metal of the substrate having a metal on its surface. In the polishing method of the present embodiment, the insulating material may be polished as an object to be polished. Examples of the insulating materials include silicon-based materials (such as silicon oxide) and organic polymers. The polishing method of the present embodiment may be performed in order to obtain a semiconductor substrate or an electronic device.

### EXAMPLES

The present invention will be described in more detail with reference to examples, but the present invention is not limited to these examples unless deviating from the technological idea of the present invention. For instance, the type and the blending ratio of the materials of the slurry may be types and ratios other than the types and the ratios described in the present examples, and the composition and the structure of the object to be polished may also be compositions and structures other than the compositions and the structures described in the present examples.

### I. Preparation of Slurry

### Example 1

X parts by mass of ultrapure water was added into a container, 10 parts by mass of ethylene glycol was poured therein, and stirring was performed. Furthermore, 0.5 parts by mass of 20 mass % colloidal silica (amount corresponding to 0.1 parts by mass as silica particle) was added to obtain a slurry. The above-described X parts by mass of ultrapure water was determined by calculating so that the total amount became 100 parts by mass.

### Example 2

2.0 parts by mass of glycine and 0.2 parts by mass of benzotriazole were added into a container, and X parts by mass of ultrapure water was poured therein, and stirring and mixing were performed so that both of the components were dissolved. Next, 1.5 parts by mass of ethylene glycol was added thereto, and stirring was performed. Furthermore, 25 parts by mass of 20 mass % colloidal silica (amount corresponding to 5.0 parts by mass as silica particle) was added to obtain a slurry. The above-described X parts by mass of ultrapure water was determined by calculating so that the total amount became 100 parts by mass.

### Examples 3 to 10 and Comparative Examples 1 to 13

Concerning each component shown in Table 1 and Table 2, a similar operation to that in Example 1 was carried out to obtain slurries.

### II. Evaluation

(Measurement for pH of Slurry)

A pH (25° C.) of each slurry was measured by use of a pH meter (Model F-51, made by Horiba Ltd. (HORIBA, Ltd.)). The measurement results are shown in Table 1 and Table 2.

(Evaluation of Dispersion Stability of Abrasive Grains)

A measurement sample was prepared by weighing out 0.5 g of each of the above-described slurries, and diluting with 99.5 g of water (200 times dilution). Next, the average particle diameter (secondary particle diameter) of the silica particles (colloidal silica) in each of these measurement samples was measured by use of a dynamic light scattering type particle size distribution meter (made by BECKMAN COULTER Inc., trade name: Model COULTER N5). A value of D50 was regarded as the average particle diameter.

The average particle diameters (secondary particle diameter) of each of the above-described slurries were measured immediately after the preparation (where “immediately after preparation” refers to period within 30 minutes after preparation, and hereinafter the same), and after storage for 14 days in a thermostatic chamber at 60° C., respectively, and a change rate (%) of the particle diameter was determined by dividing the “average particle diameter after storage−average particle diameter immediately after preparation” by “average particle diameter immediately after preparation”. The results are shown in Table 1 and Table 2.

TABLE 1

| | | | | Example | | | | |
|---|---|---|---|---|---|---|---|---|
| Item | | | Unit | 1 | 2 | 3 | 4 | 5 |
| Composition | Abrasive | Silica particle | Parts | 0.1 | 5.0 | 5.0 | 5.0 | 5.0 |
| | grain | (colloidal silica) | by | (0.5) | (25) | (25) | (25) | (25) |
| | Solvent | Ethylene glycol | mass | 10 | 1.5 | 1.5 | 1.5 | |
| | | 1,2-Butanediol | | | | | | 1.5 |
| | | 1,3-Butanediol | | | | | | |
| | | 1,4-Butanediol | | | | | | |
| | | 1,5-Pentanediol | | | | | | |
| | | Propyl propylene glycol | | | | | | |
| | | Isopropyl alcohol | | | | | | |
| | | Methanol | | | | | | |
| | | 3-Methoxy-3-methyl-1-butanol | | | | | | |
| | | 2-Butoxyethanol | | | | | | |
| | | Diisopropyl ether | | | | | | |
| | | Glycerin | | | | | | |
| | Organic acid | Glycine | | | 2.0 | | 1.0 | 2.0 |
| | | Alanine | | | | 2.0 | 1.0 | |
| | | Malic acid | | | | | | |
| | Metal | BTA | | | 0.2 | 0.2 | 0.2 | 0.2 |
| | corrosion | | | | | | | |
| | preventive | | | | | | | |
| | agent | | | | | | | |
| | Water-soluble | Acrylic acid-based | | | | | | |
| | polymer | homopolvmer | | | | | | |
| | Water | | | Remainder | Remainder | Remainder | Remainder | Remainder |
| Characteristic | pH | | — | 6.95 | 6.80 | 6.98 | 6.89 | 6.84 |
| | particle | Initial value | nm | 24.9 | 12.0 | 11.5 | 11.5 | 11.6 |
| | diameter | 60° C./14 days | | 25.0 | 12.4 | 11.8 | 11.9 | 12.5 |
| | | Change rate (14 days) | % | 0.4 | 3.3 | 2.6 | 3.5 | 7.8 |
| | | | | Example | | | | |
| Item | | | Unit | 6 | 7 | 8 | 9 | 10 |
| Composition | Abrasive | Silica particle | Parts | 5.0 | 5.0 | 5.0 | 3.0 | 5.0 |
| | grain | (colloidal silica) | by | (25) | (25) | (25) | (15) | (25) |
| | Solvent | Ethylene glycol | mass | | | | 2 | |
| | | 1,2-Butanediol | | | | | | |
| | | 1,3-Butanediol | | 1.5 | | | | |
| | | 1,4-Butanediol | | | 1.5 | | | 1.5 |
| | | 1,5-Pentanediol | | | | 1.5 | | |
| | | Propyl propylene glycol | | | | | | |
| | | Isopropyl alcohol | | | | | | |
| | | Methanol | | | | | | |
| | | 3-Methoxy-3-methyl-1-butanol | | | | | | |
| | | 2-Butoxyethanol | | | | | | |
| | | Diisopropyl ether | | | | | | |
| | | Glycerin | | | | | | |
| | Organic acid | Glycine | | 2.0 | 2.0 | 2.0 | 12.0 | 3.0 |
| | | Alanine | | | | | | |
| | | Malic acid | | | | | | |
| | Metal | BTA | | 0.2 | 0.2 | 0.2 | 0.2 | 0.2 |
| | corrosion | | | | | | | |
| | preventive | | | | | | | |
| | agent | | | | | | | |
| | Water-soluble | Acrylic acid-based | | | | | 0.3 | |
| | polymer | homopolvmer | | | | | | |
| | Water | | | Remainder | Remainder | Remainder | Remainder | Remainder |
| Characteristic | pH | | — | 6.84 | 6.86 | 6.86 | 4.90 | 6.50 |
| | particle | Initial value | nm | 11.4 | 11.7 | 11.4 | 76.6 | 116.0 |
| | diameter | 60° C./14 days | | 12.3 | 11.8 | 12.4 | 77.2 | 119.0 |
| | | Change rate (14 days) | % | 7.9 | 0.9 | 8.8 | 0.8 | 2.6 |

TABLE 2

| | | | | Comparative Example | | | | | | |
|---|---|---|---|---|---|---|---|---|---|---|
| Item | | | Unit | 1 | 2 | 3 | 4 | 5 | 6 | 7 |
| Composition | Abrasive | Silica particle | Parts | 15 | 5.0 | 0.1 | 5.0 | 5.0 | 5.0 | 5.0 |
| | grain | (colloidal silica) | by | (75) | (25) | (0.5) | (25) | (25) | (25) | (25) |
| | Solvent | Ethylene glycol | mass | | | | 1.5 | 1.5 | | |
| | | 1,2-Butanediol | | | | | | | | |
| | | 1,3-Butanediol | | | | | | | | |
| | | 1,4-Butanediol | | | | | | | | |
| | | 1,5-Pentanediol | | | | | | | | |
| | | Propyl propylene | | | | | | | 1.5 | |
| | | glycol | | | | | | | | |
| | | Isopropyl | | | | | | | | 1.5 |
| | | alcohol | | | | | | | | |
| | | Methanol | | | | | | | | |
| | | 3-Methoxy-3- | | | | | | | | |
| | | methyl-1-butanol | | | | | | | | |
| | | 2-Butoxyethanol | | | | | | | | |
| | | Diisopropyl | | | | | | | | |
| | | ether | | | | | | | | |
| | | Glycerin | | | | | | | | |
| | Organic acid | Glycine | | | 2.0 | | | 1.0 | 2.0 | 2.0 |
| | | Alanine | | | | | | | | |
| | | Malic acid | | | | | 2.0 | 1.0 | | |
| | Metal | BTA | | | 0.2 | | 0.2 | 0.2 | 0.2 | 0.2 |
| | corrosion | | | | | | | | | |
| | preventive | | | | | | | | | |
| | agent | | | | | | | | | |
| | Water-soluble | Acrylic | | | | | | | | |
| | polymer | acid-based | | | | | | | | |
| | | homopolymer | | | | | | | | |
| | Water | | | Remainder | Remainder | Remainder | Remainder | Remainder | Remainder | Remainder |
| Characteristic | pH | | — | 7.24 | 6.86 | 6.94 | 2.15 | 3.09 | 6.73 | 6.73 |
| | particle | Initial value | nm | 11.7 | 11.0 | 14.3 | 26.4 | 26.3 | 12.0 | 11.4 |
| | diameter | 60° C./14 days | | 33.8 | 12.3 | 21.5 | 40.2 | 93.8 | 17.1 | 13.5 |
| | | Change rate (14 | % | 188.9 | 11.8 | 50.3 | 52.3 | 256.7 | 42.5 | 18.4 |
| | | days) | | | | | | | | |

| | | | | Comparative Example | | | | | |
|---|---|---|---|---|---|---|---|---|---|
| Item | | | Unit | 8 | 9 | 10 | 11 | 12 | 13 |
| Composition | Abrasive | Silica particle | Parts | 5.0 | 5.0 | 5.0 | 5.0 | 5.0 | 5.0 |
| | grain | (colloidal silica) | by | (25) | (25) | (25) | (25) | (25) | (25) |
| | Solvent | Ethylene glycol | mass | | | | | | 1.5 |
| | | 1,2-Butanediol | | | | | | | |
| | | 1,3-Butanediol | | | | | | | |
| | | 1,4-Butanediol | | | | | | | |
| | | 1,5-Pentanediol | | | | | | | |
| | | Propyl propylene | | | | | | | |
| | | glycol | | | | | | | |
| | | Isopropyl | | | | | | | |
| | | alcohol | | | | | | | |
| | | Methanol | | 1.5 | | | | | |
| | | 3-Methoxy-3- | | | 1.5 | | | | |
| | | methyl-1-butanol | | | | | | | |
| | | 2-Butoxyethanol | | | | 1.5 | | | |
| | | Diisopropyl | | | | | 1.5 | | |
| | | ether | | | | | | | |
| | | Glycerin | | | | | | 1.5 | |
| | Organic acid | Glycine | | 2.0 | 2.0 | 2.0 | 2.0 | 2.0 | |
| | | Alanine | | | | | | | |
| | | Malic acid | | | | | | | 2.0 |
| | Metal | BTA | | 0.2 | 0.2 | 0.2 | 0.2 | 0.2 | 0.2 |
| | corrosion | | | | | | | | |
| | preventive | | | | | | | | |
| | agent | | | | | | | | |
| | Water-soluble | Acrylic | | | | | | | |
| | polymer | acid-based | | | | | | | |
| | | homopolymer | | | | | | | |

| | | | | | | | | |
|---|---|---|---|---|---|---|---|---|
| | Water | | Remainder | Remainder | Remainder | Remainder | Remainder | Remainder |
| Characteristic | pH | — | 6.86 | 6.86 | 6.85 | 6.87 | 6.83 | 2.40 |

| | | | | | | | | |
|---|---|---|---|---|---|---|---|---|
| particle | Initial value | nm | 11.6 | 11.5 | 12.3 | 11.5 | 11.4 | 116.0 |
| diameter | 60° C./14 days | | 12.9 | 13.0 | 14.0 | 13.0 | 12.5 | settle |
| | | | | | | | | down |
| | Change rate (14 | % | 11.2 | 13.0 | 13.8 | 13.0 | 9.6 | — |
| | days) | | | | | | | |

### III. Evaluation Results

According to each example that uses a slurry in which glycol was used as an organic solvent, an average particle diameter of abrasive grains was 120 nm or smaller, and the pH was 4.0 or higher and lower than 8.0, the change rate of the particle diameter of the abrasive grains was 9%/o or lower even when storing at 60° C. for 14 days was performed, in spite of the fact that the particle diameter of the abrasive grains was small; and it has become clear that storage stability of the abrasive grains is good. Furthermore, according to Examples 1 to 4 and 9, it has become clear that the storage stability of the abrasive grains is particularly enhanced, when ethylene glycol is used as an organic solvent. Meanwhile, according to Comparative Examples, the change rate of the particle diameter of the abrasive grains exceeded 9%, or the abrasive grains resulted in agglomerating and settling down, when storing at 60° C. for 14 days was performed; and it has become clear that the storage stability of the abrasive grains is low.

1. A slurry comprising:
abrasive grains;
a glycol; and
water, wherein
an average particle diameter of the abrasive grains is 120 nm or smaller, and
a pH is 4.0 or higher and lower than 8.0.

2. The slurry according to claim 1, wherein the pH is higher than 5.0 and lower than 8.0.

3. The slurry according to claim 1, wherein the abrasive grains comprise silica.

4. The slurry according to claim 1, wherein a mass ratio of a content of the abrasive grains with respect to a content of the glycol is 0.01 to 150.

5. The slurry according to claim 1, wherein the glycol comprises a glycol in which a number of carbon atoms of an alkylene group between two hydroxy groups is 5 or less.

6. The slurry according to claim 1, wherein the glycol comprises at least one selected from the group consisting of ethylene glycol, 1,2-butanediol, 1,3-butanediol, 1,4-butanediol and 1,5-pentanediol.

7. The slurry according to claim 1, wherein the glycol comprises ethylene glycol.

8. The slurry according to claim 1, further comprising an organic acid component.

9. The slurry according to claim 1, further comprising a metal corrosion preventive agent.

10. The slurry according to claim 1, for use in polishing a cobalt-based metal.

11. A polishing method comprising a step of polishing a metal by use of the slurry according to claim 1.

12. The polishing method according to claim 11, wherein the metal comprises a cobalt-based metal.

13. The slurry according to claim 1, wherein the glycol comprises at least one selected from the group consisting of 1,4-pentanediol, 1,5-pentanediol, 1,5-hexanediol, 1,6-hexanediol, dipropylene glycol, triethylene glycol and tripropylene glycol.

14. The slurry according to claim 1, wherein the pH is higher than 5.0 and 6.98 or lower.

15. The slurry according to claim 14, wherein the abrasive grains comprise silica.

16. The slurry according to claim 1, wherein the pH is 6.5 or higher and lower than 8.0.

17. The slurry according to claim 1, wherein a content of the glycol is 0.1 mass % or more.

18. The slurry according to claim 8, wherein the organic acid component comprises an amino acid.

19. The slurry according to claim 1, further comprising a polymer having structural unit derived from (meth)acrylic acid.

20. The slurry according to claim 1, wherein a change rate of the average particle diameter of the abrasive grains after the slurry has been stored at 60° C. for 14 days is 9% or less, wherein the change Rate (%) of the average particle diameter of the abrasive grains=(average particle diameter after storage at 60° C. for 14 days−initial average particle diameter)/(initial average particle diameter)×100
